(19) United States
(12) Patent Application Publication
(10) Pub. No.: US 2011/0140726 A1
(43) Pub. Date: Jun. 16, 2011

(54) Apparatus and Methods for Measuring Solar Cell Module Performance

(75) Inventors: Jeffrey S. Sullivan, Castro Valley, CA (US); Danny C. Lu, San Francisco, CA (US); Peter Wang, Santa Clara, CA (US); Kashif Maqsood, San Francisco, CA (US); Todd W. Martin, Mountain View, CA (US); Connie Meggs, San Jose, CA (US); Kim Vellore, San Jose, CA (US)

(73) Assignee: Applied Materials, Inc., Santa Clara, CA (US)

(21) Appl. No.: 12/950,599

(22) Filed: Nov. 19, 2010

Related U.S. Application Data
(60) Provisional application No. 61/263,654, filed on Nov. 23, 2009.
(60) Provisional application No. 61/263,880, filed on Nov. 24, 2009.

(51) Int. Cl. G01R 31/00

(52) U.S. Cl. 324/756.01

(57) ABSTRACT

Methods and apparatus for moving and evaluating the performance of solar cell modules are described. Specifically, embodiments of the invention are directed to apparatus and methods including a transparent plate having a plurality of fluid conduits therethrough, where the fluid conduits are configured to direct a fluid with sufficient force to elevate/support a solar cell module during measurement of the solar cell performance.

### CROSS-REFERENCE TO RELATED APPLICATIONS

This application claims the benefit of priority under 35 U.S.C. §119(e) to U.S. Patent Application No. 61/263,654, filed Nov. 23, 2009 and U.S. Patent Application No. 61/263,880, filed Nov. 24, 2009.

### BACKGROUND

Embodiments of the present invention relate generally to the field of photovoltaic device processing. More specifically, embodiments of the invention are directed to apparatus and methods for transferring at least partially completed photovoltaic devices such that performance testing can be performed in an unobstructed manner.

Photovoltaic panels, or solar cell modules, can be manufactured on many different size substrates. When small substrates are used, the solar cell modules can be supported by the edges without sag causing significant error in measurements. However, large glass substrates sag if supported by only the edges. Therefore, large substrates must be supported at multiple points to avoid sag and scratches to the module surface. Testing large solar cell modules is difficult because the support points obstruct the transmission of light through the module affecting the accuracy, precision and repeatability of testing measurements.

Thus, there is a need for methods and apparatus for safely moving and evaluating solar cell modules without substantially obstructing light measurements through the module.

### SUMMARY

Embodiments of the invention are directed to airbed, and methods of use, where a photovoltaic panel can float. By floating the panel, light measurements can be made without obstruction due to mechanical parts designed to support the substrate. In some specific embodiments, the airbed comprises two glass panels sandwiched with the top glass having fine holes drilled therethrough and applying pressurized air between the glass panels. In other specific embodiments, the top glass may have a slot on the sides where pressurized air may be directed towards the center of the glass. In further detailed embodiments, a side frame or “U” shaped or a complete rectangular frame may hold the substrate in place and air is applied from the frame, thereby floating the substrate.

Additional embodiments of the invention are directed to an apparatus having two parts. The first part of the conveyor will be the transition conveyor which takes the glass from the conveyor and floats it. The second part will receive the floating glass to its own floating platform which has an unobstructed light path to the entire panel.

Accordingly, one or more embodiments of the invention are directed to apparatuses for measuring the performance of a solar cell module having four edges, a front side and a back side. The apparatuses comprise a light source, a transparent sheet positioned above the light source and fluid conduits positioned and configured to direct fluid at a force sufficient to support a solar cell above the transparent sheet. The transparent sheet and the fluid conduits positioned so that light from the light source directed at the solar cell module is substantially unobstructed by the transparent sheet, the fluid conduits and the fluid.

In some embodiments, the fluid conduits pass through the transparent sheet. In detailed embodiments, the fluid conduits are aligned to direct a flow of fluid toward a middle portion of the solar cell.

In detailed embodiments, the apparatuses further comprises a frame member positioned adjacent the transparent sheet, the frame member adapted to surround the edges of the solar cell module. In specific embodiments, the fluid conduits pass through the frame member. In further specific embodiments, the fluid conduits direct the fluid between the solar cell module and the transparent sheet. According to some detailed embodiments, the frame member is configured to contact two opposite edges of the solar cell. In some detailed embodiments, the frame member is configured to contact three edges of the solar cell. In further specific embodiments, the frame member is configured to contact all four edges of the solar cell.

One or more embodiments further comprise a transition conveyor located adjacent the transparent sheet, the transition conveyor configured to transition the solar cell module from a processing conveyor to the transparent sheet.

Additional embodiments of the invention are directed to methods of evaluating performance of a solar cell module comprising a plurality of solar cells. A fluid is flowed beneath a solar cell module to elevate the solar cell module over a transparent sheet. The light to energy conversion of at least one solar cell on the solar cell module is measured.

Detailed embodiments further comprise transferring the solar cell module from a conveyor to the fluid flow over the transparent sheet. Specific embodiments, further comprising evaluating the light to energy conversion measure to determine the functionality of at least one solar cell on the solar cell module.

According to some embodiments, the fluid flow is applied by directing a fluid from about an outer edge of the solar cell module toward a center portion of the solar cell module. In some detailed embodiments, wherein measuring the light to energy conversion comprises directing light through the air bed and the fluid flow toward the solar cell module. In specific embodiments, measuring the light to energy conversion further comprises measuring the potential across at least one solar cell. In further specific embodiments, the directed light is substantially unhindered by the transparent sheet and the fluid flow.

Additional embodiments of the invention are directed to apparatuses for evaluating performance of one or more solar cells on a solar cell module. The apparatuses comprise a transparent sheet, a plurality of fluid conduits passing through the transparent sheet and a light source beneath the transparent sheet. The plurality of fluid conduits have open ends on a top surface of the transparent sheet, and are configured to direct a fluid flow over the transparent sheet. The fluid flow sufficient to elevate and support the solar cell module above the transparent sheet.

In some embodiment, the fluid conduits are configured so that the open ends positioned near edges of the solar cell module and the fluid conduits direct the fluid flow toward a center portion of the solar cell module. In detailed embodiments, light from the light source transmitted through the transparent sheet is substantially unobstructed by the transparent sheet, the fluid flow and the fluid conduits.

### BRIEF DESCRIPTION OF THE DRAWINGS

A more particular description of the invention, briefly summarized above, may be had by reference to the embodiments thereof that are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a side view of an apparatus according to one or more embodiments of the invention;

FIG. 1B is a top view of an apparatus according to one or more embodiments of the invention;

FIGS. 2A through 2C show cross-sectional views of transparent sheet according to various embodiments of the invention;

FIG. 3 shows a cross-sectional view of a support frame according to one or more embodiments of the invention;

FIG. 4A shows a top view of a substrate supported by a side frame according to one or more embodiments of the invention;

FIG. 4B shows a top view of a substrate supported by a u-shaped frame according to one or more embodiments of the invention; and

FIG. 4C shows a top view of a substrate supported by a rectangular frame according to one or more embodiments of the invention.

To facilitate understanding, identical reference numerals have been used, wherever possible, to designate identical elements that are common to the figures. It is to be understood that the embodiments shown in the figures are not drawn to scale.

### DETAILED DESCRIPTION

As used in this specification and the appended claims, the terms “solar cell module”, “solar cell device”, “photovoltaic module”, “photovoltaic device” and the like are used interchangeably to describe a photovoltaic device having a plurality of individual “photovoltaic cells” or “solar cells” thereon.

As used in this specification and the appended claims, the term “air bed” refers to a transparent plate separated from a partially completed solar cell module by a layer of fluid. The fluid can be any suitable fluid including, but not limited to, air and other gases.

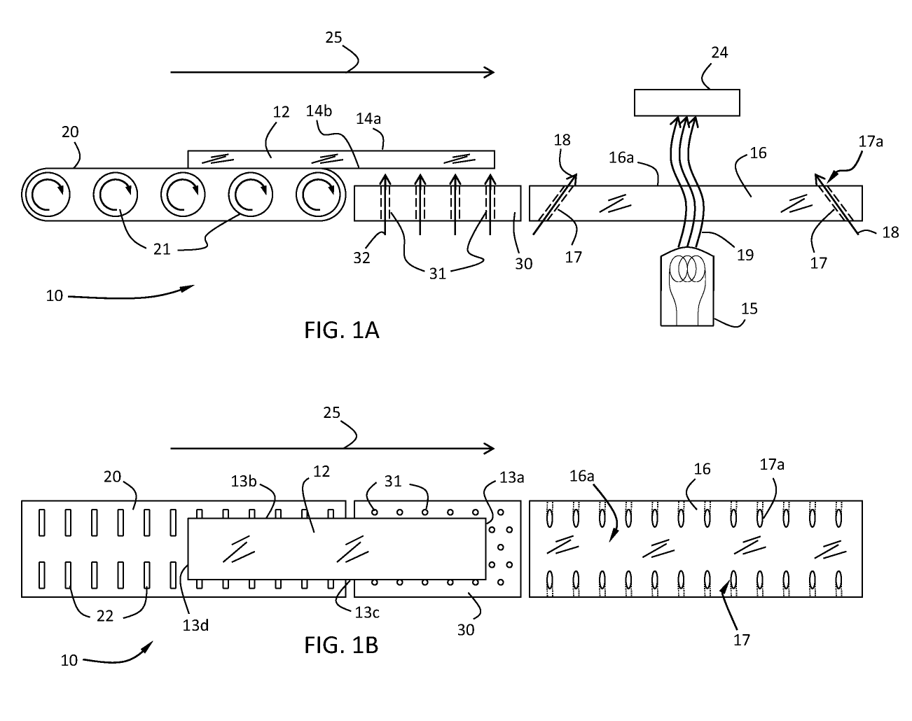

FIGS. 1A and 1B illustrate an apparatus 10 according to one or more embodiments of the invention. The apparatus 10 is suitable for safely moving a solar cell module 12 and evaluating the solar cell module 12. The solar cell module 12 shown have four edges 13, a front side 14a and a back side 14b. A solar cell module 12 being processed is transported by a suitable conveyor mechanism, also referred to as a processing conveyor. As shown in FIGS. 1A and 1B, the conveyor is a conveyor belt 20 driven by a plurality of wheels 21 in a direction to move the solar cell module 12 along direction 25. To minimize contact with the solar cell module 12, the conveyor belt 20 may have a plurality of projections 22 which support the solar cell module 12.

When the solar cell module 12 reaches the end of the conveyor belt 20, the solar cell module 12 is passed to a transition conveyor 30. The transition conveyor 30 is an optional component and, if present, is configured to transition the solar cell module 12 from the conveyor belt 20 to a transparent sheet 16. As shown in the exemplary embodiment of FIGS. 1A and 1B, the transition conveyor 30 is a plate having a plurality of fluid conduits 31. A fluid 32 passing through the fluid conduits 31 can help transition the solar cell module 12 from the conveyor belt 20 to the transparent sheet 16. The transition conveyor 30 can be made of any suitable material or thickness. It will of course be understood that the fluid can be supplied from any suitable source such as a compressed gas container, a compressor or any other suitable source for providing a pressurized gas stream at a force sufficient to elevate/support the module 12, which will be described further below.

The transition conveyor 30 shown in FIGS. 1A and 1B can pass the solar cell module 12 to the transparent sheet 16 positioned over a light source 15. The transparent sheet 16 has fluid conduits 17 positioned and configured to direct, or flow, a fluid 18 beneath the solar cell module 12, the fluid 18 flow being of sufficient force to elevate/support the solar cell module 12 over the transparent sheet 16.

The transparent sheet and the fluid conduits are positioned so that light 19 from the light source 15 directed at the solar cell module 12 is substantially unobstructed by the transparent sheet 16, the fluid conduits 17 and the fluid 18. The light 19 may be detected by a suitable detector 24. The detector 24 can be configured to detect light 19, the light to energy conversion, to detect electrical current or potential in the solar cell module 12 or individual solar cells of the solar cell module 12.

As used in this specification and the appended claims, the term “substantially unobstructed” means that the transparent sheet 16 does not absorb or reflect enough light to cause a relative error in measurement greater than about 5%. Additionally, the fluid conduits 17 are positioned along the edges 13b, 13c of the solar cell module 12. Other variants in the positioning of the fluid conduits may be used so long as the positioning does not substantially interfere with the measurement of the module performance. It will be appreciated that the conduits 17 can be separately connected to a fluid source, or they may be commonly connected to the same fluid source. A variety of ways can be utilized to connect the conduits 17 to the fluid source. For example, piping or hose may be utilized to connect each conduit 17 to the fluid source (not shown). Alternatively a single pipe or hose can be connected to a manifold or a distribution plate associated with the transparent sheet 16, so long as the manifold or distribution plate does not interfere with the light transmission from light source 15. Alternatively, distribution channels can be formed within the transparent sheet 16, so long as they do not substantially interfere with light transmission through the transparent sheet 16. One way that this can be accomplished is forming distribution channels connected to the conduits 17 in the outer periphery of the transparent plate 16.

In detailed embodiments, the light source 15, light 19 and detector 24 are used to evaluate the light to energy conversion to determine the functionality of at least one solar cell (not shown) on the solar cell module 12. In some detailed embodiments, measuring the light to energy conversion comprises directing light 19 through the transparent sheet 16 and the fluid 18 flow toward the solar cell module 12. In specific embodiments, measuring the light to energy conversion further comprises measuring the electrical potential across at least one solar cell (not shown) on the solar cell module 12.

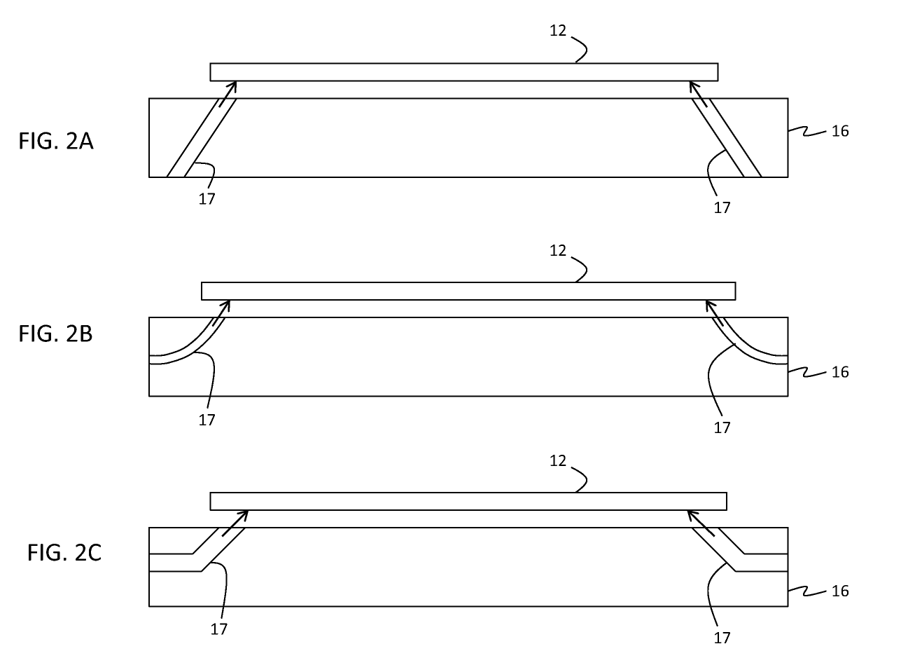

In one or more embodiments, the fluid conduits 17 pass through the transparent sheet 16. The shape of the fluid conduits 17 can be varied depending on machining requirements and ease of construction. FIGS. 2A through 2C show variations of fluid conduits 17 for use with one or more embodiments of the invention. In detailed embodiments, the fluid conduits 17 are aligned to direct a flow of fluid 18 from about an outer edge of the solar cell module 12 toward a center or middle portion of the solar cell module 12.

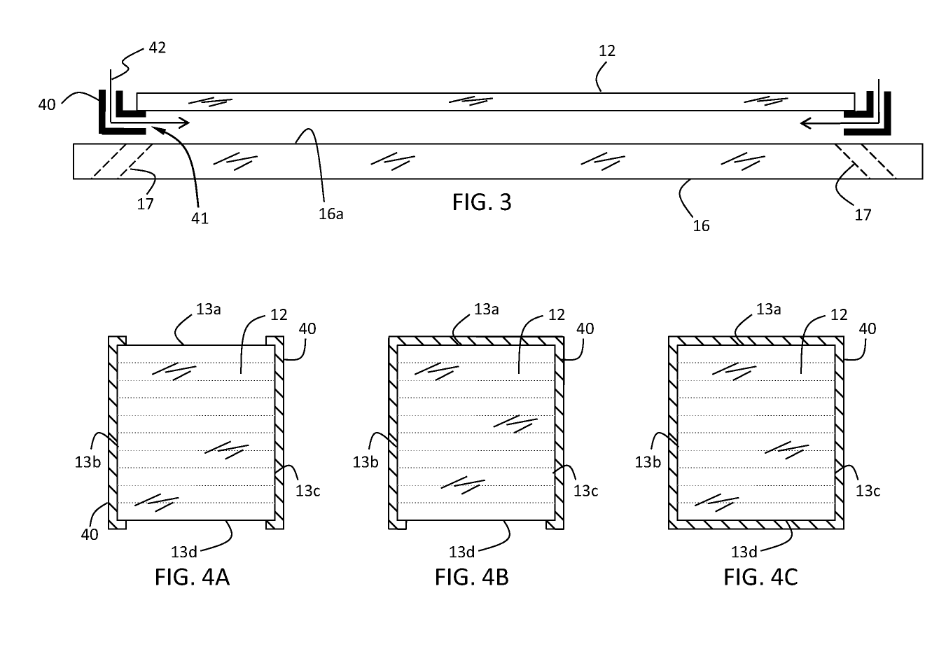

With reference to FIG. 3, one or more embodiments of the apparatus 10 use a frame member 40 to float the solar cell module 12. The frame member 40 can be positioned adjacent the transparent sheet 16 and surrounds the edges 13 of the solar cell module 12. In detailed embodiments, shown in FIG. 3, the frame member 40 includes fluid conduits 41 which pass through the frame member 40. In specific embodiments, the fluid conduits 41 are configured to direct the flow of fluid 42 between the solar cell module 12 and the transparent sheet 16. When a frame member 40 is used to float the solar cell module 12, the fluid conduits 17 in the transparent sheet 16 are optional.

FIG. 4 shows a variety of configurations of frame members 40 for use with one or more embodiment of the invention. The grid lines shown on each of the solar cell modules 12 represent scribe lines separating individual solar cells. In the embodiment exemplified by FIG. 4A, the frame member 40 is configured to contact the two opposite edges 13b and 13c. In the embodiment of FIG. 4B, the frame member 40 contacts three edges 13a, 13b and 13c of the solar cell module 12. FIG. 4B shows edges 13a, 13b and 13c in contact with the frame member 40, but this is merely illustrative. It is contemplated that the frame member 40 can contact any adjoining three sides of the solar cell module 12. FIG. 4C shows a frame member 40 in contact with all four edges 13 of the solar cell module 12.

A detailed embodiment of the invention is directed to an apparatus 10 for evaluating one or more solar cells on a solar cell module 12. The apparatus 10 comprises a transparent sheet 16, a plurality of fluid conduits 17 passing through the transparent sheet 16 and a light source 15 beneath the transparent sheet. The plurality of fluid conduits 17 have open ends 17a on the top surface 16a of the transparent sheet 16. The conduits 17 are configured to direct a fluid 18 flow over the transparent sheet 16, the fluid 18 flow having sufficient force to elevate and support a solar cell module 12 above the transparent sheet 16.

In a further detailed embodiment, the fluid conduits 17 are configured so that the open ends are positioned near edges of the solar cell module 12 and the fluid conduits 17 direct the fluid 18 flow toward a center portion of the solar cell module 12. In specific embodiments, light 19 from the light source 15 transmitted through the transparent sheet 16 is substantially unobstructed by the transparent sheet 16, the fluid 18 flow and the fluid conduits 17.

Although the invention herein has been described with reference to particular embodiments, it is to be understood that these embodiments are merely illustrative of the principles and applications of the present invention. It will be apparent to those skilled in the art that various modifications and variations can be made to the method of the present invention without departing from the spirit and scope of the invention. Thus, it is intended that the present invention include modifications and variations that are within the scope of the appended claims and their equivalents.

What is claimed is:

1. An apparatus for measuring performance of a solar cell module having four edges, a front side and a back side, the apparatus comprising:
a light source;
a transparent sheet positioned above the light source; and
fluid conduits positioned and configured to direct fluid at a force sufficient to support a solar cell above the transparent sheet, the transparent sheet and the fluid conduits positioned so that light from the light source directed at the solar cell module is substantially unobstructed by the transparent sheet, the fluid conduits and the fluid.

2. The apparatus of claim 1, wherein the fluid conduits pass through the transparent sheet.

3. The apparatus of claim 2, wherein the fluid conduits are aligned to direct a flow of fluid toward a middle portion of the solar cell.

4. The apparatus of claim 1, further comprising a frame member positioned adjacent the transparent sheet, the frame member adapted to surround the edges of the solar cell module.

5. The apparatus of claim 4, wherein the fluid conduits pass through the frame member.

6. The apparatus of claim 5, wherein the fluid conduits direct the fluid between the solar cell module and the transparent sheet.

7. The apparatus of claim 4, wherein the frame member is configured to contact two opposite edges of the solar cell.

8. The apparatus of claim 4, wherein the frame member is configured to contact three edges of the solar cell.

9. The apparatus of claim 4, wherein the frame member is configured to contact all four edges of the solar cell.

10. The apparatus of claim 1, further comprising a transition conveyor located adjacent the transparent sheet, the transition conveyor configured to transition the solar cell module from a processing conveyor to the transparent sheet.

11. A method of evaluating performance of a solar cell module comprising a plurality of solar cells, the method comprising:
flowing a fluid beneath a solar cell module to elevate the solar cell module over a transparent sheet; and
measuring a light to energy conversion of at least one solar cell on the solar cell module.

12. The method of claim 11, further comprising transferring the solar cell module from a conveyor to the fluid flow over the transparent sheet.

13. The method of claim 11, further comprising evaluating the light to energy conversion measure to determine the functionality of at least one solar cell on the solar cell module.

14. The method of claim 11, wherein the fluid flow is applied by directing the fluid from about an outer edge of the solar cell module toward a center portion of the solar cell module.

15. The method of claim 11, wherein measuring the light to energy conversion comprises directing light through the transparent sheet and the fluid flow toward the solar cell module.

16. The method of claim 15, wherein measuring the light to energy conversion further comprises measuring potential across at least one solar cell.

17. The method of claim 15, wherein the directed light is substantially unhindered by the transparent sheet and the fluid flow.

18. An apparatus for evaluating performance of one or more solar cells on a solar cell module, the apparatus comprising:
a transparent sheet;
a plurality of fluid conduits passing through the transparent sheet and having open ends on a top surface of the transparent sheet, the plurality of fluid conduits configured to direct a fluid flow over the transparent sheet, the fluid flow sufficient to elevate and support the solar cell module above the transparent sheet; and
a light source beneath the transparent sheet.

19. The apparatus of claim 18, wherein the fluid conduits are configured so that the open ends positioned near edges of the solar cell module and the fluid conduits direct the fluid flow toward a center portion of the solar cell module.

20. The apparatus of claim 19, wherein light from the light source transmitted through the transparent sheet is substantially unobstructed by the transparent sheet, the fluid flow and the fluid conduits.
